(19) United States
(12) Patent Application Publication
(10) Pub. No.: US 2026/0119736 A1
(43) Pub. Date: Apr. 30, 2026

(54) METHOD FOR SETTING UP AN ELECTRICAL TRANSPORTATION INFRASTRUCTURE OF A MINE, METHOD OF MINING IN A MINE, AND A PLANNING SYSTEM FOR A MINE

(71) Applicant: ABB Schweiz AG, Baden (CH)

(72) Inventors: Nicholas Hall, Windisch (CH); Bernhard Primas, Mannheim (DE); Theresa Loss, Mannheim (DE); Christoph Schlegel, Baden-Dättwil (CH); Nic Beutler, Zürich (CH); Eike Fokken, Eppelheim (DE); Ruben Huehnerbein, Heidelberg (DE)

(21) Appl. No.: 19/429,559

(22) Filed: Dec. 22, 2025

Related U.S. Application Data
(63) Continuation of application No. PCT/EP2024/066101, filed on Jun. 11, 2024.

(30) Foreign Application Priority Data
Jun. 30, 2023 (WO) PCT/EP2023/068040

(51) Int. Cl. G06F 30/18; G06Q 10/0631; G06Q 50/02

(52) U.S. Cl. CPC G06F 30/18; G06Q 10/06315; G06Q 50/02

(57) ABSTRACT

A method for setting up an electrical transportation infrastructure in a mine includes receiving mining data for different time periods of a mining interval. The data identifies expected source locations where material is extracted and destination locations where it is delivered. Using this data, a time-dependent 3D network of the mine is determined for each period, either as separate networks of paths connecting the source and destination locations or as a single network covering all periods. Based on this network, a planned placement of the electrical transportation infrastructure is numerically determined to at least approximately minimize the expected total costs of the mine over the mining interval. These costs include estimated environmental costs from transporting material between source and destination locations, subject to mining constraints. Finally, the electrical transportation infrastructure is initialized in the mine according to the planned placement.

### CROSS-REFERENCE TO RELATED APPLICATIONS

This application is a continuation of International Patent Application No. PCT/EP2024/066101, filed on Jun. 11, 2024, and titled “METHOD FOR SETTING UP AN ELECTRICAL TRANSPORTATION INFRASTRUCTURE OF A MINE, METHOD OF MINING IN A MINE, AND A PLANNING SYSTEM FOR A MINE”, which claims priority to International Patent Application No. PCT/EP2023/068040, filed on Jun. 30, 2023, and titled “METHOD FOR SETTING UP AN ELECTRICAL TRANSPORTATION INFRASTRUCTURE OF A MINE, METHOD OF MINING IN A MINE, AND A PLANNING SYSTEM FOR A MINE”, the entire contents of which are hereby incorporated by reference.

### TECHNICAL FIELD

Aspects of the present disclosure relate to a method for setting up an electrical transportation infrastructure (TI) of a mine. In particular, the present disclosure relates to a mine with more than one source location of the material to be mined, and even more particular, a respective open pit mine, a corresponding computer program product and/or a computer-readable medium, a planning system for the mine, and a method of mining.

### BACKGROUND

In a mine, material is dug out of the ground and moved to specific locations. From there the material may be transferred to a processing plant where the minerals can be extracted. The mining process is comparatively energy-intensive and associated with a corresponding ecological footprint. Currently, the mining industry is responsible for several percent of greenhouse gas emissions, in particular CO₂ emissions. Any reduction in the emission of these gases due to mining can be very beneficial for the climate. Accordingly, not only customers increasingly request CO₂-neutral value chains but there are already legal requirements for compensating CO₂ emissions. Accordingly, further improving mining processes is desired.

### BRIEF DESCRIPTION

In view of the above, and for other reasons, there is a need for the present disclosure. Thus, according to the independent claims, respective typically computer-implemented methods, and a planning system for performing said methods as well as respective computer program products and computer-readable media are provided.

According to an aspect of a method for setting up an electrical transportation infrastructure of a mine, the method includes receiving, for different time periods of a given mining time interval, in particular subsequent time periods of the given mining time interval, mining data for the mine, the mining data including respective expected source locations, where a material is to be taken from, and at least one respective destination location, where the material is to be taken to. The method further includes determining, using the mining data, a time-dependent 3D network of the mine. The time-dependent 3D network includes a single network of paths connecting the expected source locations with at least one destination location during any of the different time periods and information indicating during which time period each path is present. Alternatively, or in addition, the network includes, for each of the different periods, a respective network of (available) paths connecting the expected source locations with at least one destination location during the respective time period. The method further includes numerically determining, using the time-dependent 3D network, a planned placement of the electrical transportation infrastructure so that expected total costs of the mine over the given mining time interval are at least approximately minimized. The expected total costs of the mine includes estimated environmental costs resulting from transporting the material between the expected source locations and at least one destination location during the given mining time interval. In particular, the expected total costs of the mine typically includes estimated environmental costs resulting from transporting the material between the expected source locations and at least one destination location during the given mining time interval subject to mining constraints during the given mining time interval (when taking into account the mining constraints during the given mining time interval).

In the following, the information during which of the time periods each path is present (may be used for material transportation) is also referred to as time information for short. The time information may be stored separately. However, more typically the time information is stored within the single network of paths, in particular indirectly, for example as (time dependent) attributes of the paths and more specifically, as (time dependent) attributes of the edges of the single network formed by roads connecting the source locations with at least one destination location at the respective time period. Note that “a path” between a source location and a destination location may be formed by one edge representing a road connecting the source location and the destination location, but may, due to other nodes (such as road crossings or road junctions), also include two or even more edges.

Further, the method typically includes (at least) initializing by placing the electrical transportation infrastructure in the mine based on the planned placement of the electrical transportation infrastructure. Initializing by placing the electrical transportation infrastructure in the mine may, for example, include generating respective planning documents for the electrical transportation infrastructure, at least coordinating building (setting up) the electrical transportation infrastructure and/or at least coordinating the change of the electrical transportation infrastructure during the given mining time interval.

Typically, the methods for setting up the electrical transportation infrastructure as explained herein are methods of setting up the electrical transportation infrastructure. Accordingly, the methods typically includes building (setting up) the electrical transportation infrastructure and/or changing the electrical transportation infrastructure during the given mining time interval.

The method for setting up the electrical transportation infrastructure allows for efficient electrification of transportation of the mine and/or reducing the ecological footprint during mining in the mine. In particular, the transport of the material in a mine can at least partly be covered electrically, for example by an electric power supply infrastructure such as electric trolley lines or an electric rail system in combination with electrified haulage trucks. Thereby, fossil fuel consumption, such as diesel consumption of respective trucks or any other respective mining vehicle infrastructure, can be reduced. As the rated electric output power of renewable electrical energies sources (sources of green energy) such as wind farms (wind power plants), solar farms (solar power plants), and combinations thereof increases and are even becoming more competitive in terms of costs, the ecological footprint of mining can be significantly reduced by providing an appropriate electrical transportation infrastructure.

In a longer term perspective, many trucks are expected to be equipped with an electrical battery, which is able to get charged in motion by electric trolley lines or an electric rail system, or at stationary charging stations. In this case, the fossil fuel consumption can be lowered to zero.

Since the mine changes over time and especially the source locations (also known as in-pit mining locations) typically vary over time, the placement of the electrical transportation infrastructure, particularly an electric power supply infrastructure of the electrical transportation infrastructure, which may also be referred to as electric transport infrastructure, such as trolley lines is often challenging. This is because there is usually a lot of optimization potential in locating the electrical transportation infrastructure in long-lived parts of the mine. Accordingly, considering each time period of the given mining time interval individually for the optimal placement during the different time periods is usually not sufficient. The term “electrical transportation infrastructure” as used in this specification intends to describe an electric power supply infrastructure for vehicles that may be used to transport the material in the mine.

By using the mining data, for example a planned mining schedule to (numerically) determine the time-dependent 3D network of the mine and determining the planned placement of the electrical transportation infrastructure (TI) based on the time-dependent 3D network so that the expected total costs of the mine (including the estimated environmental costs) over the given mining time interval are at least approximately minimized, the resulting placement of the electrical transportation infrastructure allows for significantly reducing the mine's consumption of fossil fuels and its ecological footprint, respectively.

While the placement of the electrical transportation infrastructure is typically fixed during the respective time period, it may also either be fixed for the given mining time interval, or, more typically time-dependent. The latter may be due to changing the source location(s). Likewise, the time-dependent 3D network is typically a time-dependent 3D road network.

The planned placement of the electrical transportation infrastructure may be determined using known (numerical) optimizations algorithms to find a local or even a global minimum of the expected total costs of the mine (including the estimated environmental costs) over the given mining time interval so that the constraints of mining (mining constraints), more typically all of the mining constraints, are met during the given mining time interval.

Typically, the given mining time interval, which may also be referred to as given mining time horizon, is larger than one year, two years or even several years, and/or refers to an expected overall mining time of the mine. The mining constraints may in particular refer to transportation time for the material, production schedule of the mine, production capacity of the mine, production efficiency of the mine, and cost information such as (spot) market price(s) or projected commodity price(s) and capital costs. In particular, at least (weighted) production capacity and efficiency of the mine, which should typically be as high as possible (be maximized) may form mining constrains to be met.

Typically, the environmental costs refer to (expected) greenhouse gas (GHG) emissions, in particular carbon dioxide (CO₂) emissions during the given mining time interval. For example, the environmental costs may include the (expected) costs for compensating GHG (CO₂) emissions during the given mining time interval such as costs for CO₂ certificates often considered as a key instrument in decarbonising or a CO₂ tax.

For the sake of simplicity, this specification focuses with respect to environmental costs on CO₂ as GHG. This is however not to be understood as limiting. The environmental costs may also refer to emissions of other GHGs such as nitrous oxide (N₂O) resulting from transporting the material during the given mining time interval, as well as any other environmental costs associated with the mining processes.

The expected total costs of the mine that is to be at least approximately minimized typically includes capital expenditures (CapEx) of the mine, in particular costs for fixed assets such as equipment, machinery, and trucks, and operating expenses (OpEx) of the mine, in particular costs for running the mine's day-to-day operations such as energy costs. Further, the estimated environmental costs may also be considered as providing parts of CapEx and OpEx. Particularly, the CapEx of the mine may include CapEx of the electrical transportation infrastructure provided by a first portion of the estimated environmental costs, and the OpEx of the mine may include OpEx of the electrical transportation infrastructure provided by a second (remaining) portion of the estimated environmental costs.

Performing the optimization in terms of costs for finding the electrical transportation infrastructure to be used in the mine not only allows for reducing the GHG (CO₂) emissions and/or finding an (at least approximately/substantially) optimal trade-off between costs and the emissions, but also comes along with the additional benefit that the cost-planning of the mine may partially be shifted from the (regular) OpEx costs to (one-time) CapEx costs. In particular, OpEx costs (as well as expected total costs) may be reduced by using the electrical transportation infrastructure, for example trolley lines, and CapEx costs for building as well as changing the electrical transportation infrastructure during the lifetime of the mine may be increased.

Optimization may be performed by at least approximately minimizing the total cost including the environmental costs. For example, numerically determining the planned placement of the electrical transportation infrastructure may include using a placement algorithm for the electrical transportation infrastructure at least approximately minimizing the total costs including the estimated environmental costs resulting from transporting the material (between the expected source locations and the destination location(s)) during the given mining time interval for a given budget of the electrical transportation infrastructure.

Alternatively, optimization may be performed for a given (fixed, financial) budget (for the transportation infrastructure) by numerically determining the electric transportation infrastructure for the mine at the given budget so that the estimated environmental costs (in particular for GHG emissions) are (at least approximately) minimized. Optionally, this optimization may be performed for different budgets to find a good trade-off between the budget for the transportation infrastructure and the estimated environmental costs (ecological footprint).

In this aspect, the method for setting up the electrical transportation infrastructure of the mine typically includes receiving mining data for the mine, for different time periods of a given mining time interval, in particular subsequent time periods of the given mining time interval, the mining data comprising respective expected source locations, where a material is to be taken from, and at least one respective destination location, where the material is to be taken to. It also includes determining, using the mining data, a time-dependent 3D network of the mine for each of the different periods, the time-dependent 3D network including a respective network of available paths connecting the expected source locations with the least one destination location during the respective time period. Additionally, the method includes numerically determining, for a given budget of the electrical transportation infrastructure and using the time-dependent 3D network, a planned placement of the electrical transportation infrastructure using a placement algorithm that at least approximately minimizes the estimated environmental costs resulting from transporting the material between the expected source locations and at least one destination location during the given mining time interval, subject to mining constraints during the given mining time interval.

In this aspect, the planned placement of the electrical transportation infrastructure is also typically determined such that expected total costs of the mine over the given mining time interval are at least approximately minimized. Further, the given budget typically includes the CapEx of the electrical transportation infrastructure, and the OpEx of the electrical transportation infrastructure such as expected energy costs for transporting the material using the electrical transportation infrastructure (during the given mining time interval). The OpEx of the mine may also include expected energy costs for transporting the material without using the electrical transportation infrastructure, for example fuel cost of conventional or hybrid trucks if used.

Typically, the placement algorithm is an optimization algorithm with respective penalty terms for the budget of the electrical transportation infrastructure and the environmental costs, in particular the GHG emissions. In typical embodiments, the electrical transportation infrastructure includes conductor rails and/or power lines, in particular trolley lines for the transport vehicles such as respective trucks.

Alternatively or in addition, the electrical transportation infrastructure may include at least one charging station for electric trucks. During optimizing, a substantially optimal placement of the charging station(s) can typically be determined so that charging/waiting times of the electric trucks are (substantially) minimized. Further, the location of material storage (as destination location), which is used to shift loads in time for optimization of the mining schedule, may be determined during optimization.

Furthermore, even electrical grid planning in combination with the location of the conductor rails or trolley lines to ensure robustness and efficiency of the grid may be considered during optimizing.

According to an embodiment, the placement algorithm is a heuristic algorithm. Heuristic approaches are typically easy to implement (comparatively) and can yield solutions which are close to the optimal solution. In this embodiment, the placement algorithm may include at least one, typically all, of the following. It may include assigning a weight (that may also be referred to as value) for each edge of the respective networks, the weights indicating how desired it is to transport the material on the edges using a respective electrical transportation infrastructure of the edge. It may also include determining an overlay of the respective networks or a single network of paths as explained herein. The weights may also be used to select an edge of the overlay (or the single network of paths) that is most desired to be equipped with a respective electrical transportation infrastructure. The placement algorithm may also include updating the expected total costs or costs (C_{B}) of building the electrical transportation infrastructure in accordance with costs for installing the respective electrical transportation infrastructure at the selected edge. These activities may be repeated until the expected total cost at least reaches a total budget or the costs (C_{B}) of building the electrical transportation infrastructure at least reaches the given budget.

The weights typically depend on at least one of, typically several of or even all of: a length of the edge, a slope of the edge, an elevation profile of the edge, the time periods, the mass of the material to be transported along the edges during the respective time period, an expected energy consumption and/or emitted amount GHG for using the electrical transportation infrastructure of the respective edge, and an expected energy consumption and/or emitted amount GHG for using an alternative energy source for transporting the material along the respective edge, in particular a respective fossil fuel consumption (for example a diesel consumption). Other factors on which the weights may depend on are the vehicle (empty) mass, a recuperation factor of the respective vehicle, and a typically velocity dependent and/or load-dependent drag coefficient of the respective vehicle.

According to another embodiment, the placement algorithm uses mixed integer linear programming (MILP). In this embodiment, the placement algorithm may include at least one, typically all, of the following. The placement algorithm may include, for each of the different time periods, determining for each edge of a graph representing the time-dependent 3D network (during the respective time period) the costs of building the electrical transportation infrastructure at and/or along the edge. For each of the different time periods, it may also determine, for each edge of the graph, the respective costs referring to an emitted GHG amount resulting from transporting the material along the edge when the electrical transportation infrastructure is used and when a non-electrical transportation infrastructure is used, such as a diesel truck, in particular a respective emitted CO₂ amount. The placement algorithm can then use a MILP solver to minimize a function comprising the costs of building the electrical transportation infrastructure and the costs referring to the emitted GHG, subject to the constraint that a given budget for the electrical transportation infrastructure is not exceeded.

The MILP solver may in particular be a Gurobi, CPLEX, Highs, or CBC-solver. Compared to the heuristic approach, the use of a MILP solver is typically more numerically intensive, but is expected to provide a more accurate solution.

According to an aspect of a method of mining in a mine, which is in the following also referred to as mining method, the method includes determining mining data relating to the mine, storing the mining data in a database, receiving the mining data from the database, and selecting the time periods in accordance with expected life times of expected source locations of the mine. The mining further includes setting up an electrical transportation infrastructure of the mine or adapting the electrical transportation infrastructure of the mine according to any of the methods for setting up an electrical transportation infrastructure of a mine as explained herein, and transporting the material using the electrical transportation infrastructure of the mine.

Setting up the electrical transportation infrastructure of the mine may be performed prior to the start of mining the material, but also after mining has started, in particular repeated after detecting unexpected material quality at one of the expected source locations of the mine and/or regularly. Accordingly, the optimization as described herein may be performed not only prior to mining but also during mining. The material or a part or fraction thereof may be transported as raw material (excavated material) or as processed material, for example crushed raw material, in particular by corresponding vehicles, which are at least temporarily supplied with electric power from an electric power supply infrastructure of the electrical transportation infrastructure, such as corresponding rails or trolleys.

According to another aspect, a computer program product or a (non-transitory) computer-readable medium includes instructions which, when executed by a computer, cause the computer to carry out any of the methods as explained herein.

According to an aspect of a planning system for a mine including a time-dependent road network with edges formed by roads connecting source locations with at least one destination location of the mine, wherein at least one edge of the road network is, for at least one time period of a given (expected) mining time interval, to be provided with a respective electrical transportation infrastructure such as a conductor rail and/or a power line (for transporting material), in particular a trolley line, the planning system is configured for carrying out any of the methods as explained herein.

According to another aspect, a mine includes a typically time-dependent road network comprising edges formed by roads connecting source locations with at least one destination location of the mine. At least one edge of the road network is, for at least one time period of a given (expected) mining time interval, provided with a respective electrical transportation infrastructure for electrical supply of vehicles for transporting material between the expected source locations and at least one destination location during mining (transport vehicles, for example respective trucks), such as a conductor rail and/or a power line, i particularly a trolley line. Typically, the respective electrical transportation infrastructure is placed in accordance with any of the methods for setting up the electrical transportation infrastructure as explained herein.

The methods, devices and systems described herein allow for a cost reduction or even minimization in the electrification of mines as well as a reduction of GHG (CO₂) emissions, which is increasingly important with ongoing efforts and regulations to reduce those emissions and other environmental impacts. Further advantages, features, aspects and details that can be combined with embodiments described herein are evident from the dependent claims, the description and the drawings.

### BRIEF DESCRIPTION OF DRAWINGS

The details will be described in the following with reference to the figures.

FIG. 1A is a flow chart of a method for setting up an electrical transportation infrastructure of a mine according to an embodiment.

FIG. 1B is a schematic view of a mine according to an embodiment.

FIG. 1C is a flow chart of a method for setting up an electrical transportation infrastructure of a mine according to an embodiment.

FIG. 1D is a flow chart of a method for setting up an electrical transportation infrastructure of a mine according to an embodiment.

FIG. 1E illustrates a method for setting up an electrical transportation infrastructure of a mine according to an embodiment.

FIG. 1F is a flow chart of a method of mining in a mine according to an embodiment.

FIG. 2A and FIG. 2B further illustrates the method for setting up an electrical transportation infrastructure of the mine shown in FIG. 1D according to embodiments.

FIGS. 3A and 3B illustrates a method for setting up an electrical transportation infrastructure of a mine according to an embodiment.

### DETAILED DESCRIPTION

Reference will now be made in detail to the various embodiments, one or more examples of which are illustrated in each figure. Each example is provided by way of explanation and is not meant as a limitation. For example, features illustrated or described as part of one embodiment can be used on or in conjunction with any other embodiment to yield yet a further embodiment. It is intended that the present disclosure includes such modifications and variations.

Within the following description of the drawings, the same reference numbers refer to the same or to similar components. Generally, only the differences with respect to the individual embodiments are described. Unless specified otherwise, the description of a part or aspect in one embodiment applies to a corresponding part or aspect in another embodiment as well.

Further, in the given embodiments below, trolley lines are used exemplary for the mine's electrical transportation infrastructure to illustrate the general aspects described above. The described method and system can be equally applicable for other types of electrical transportation infrastructure such as electric charging stations for battery-powered transport vehicles (trucks).

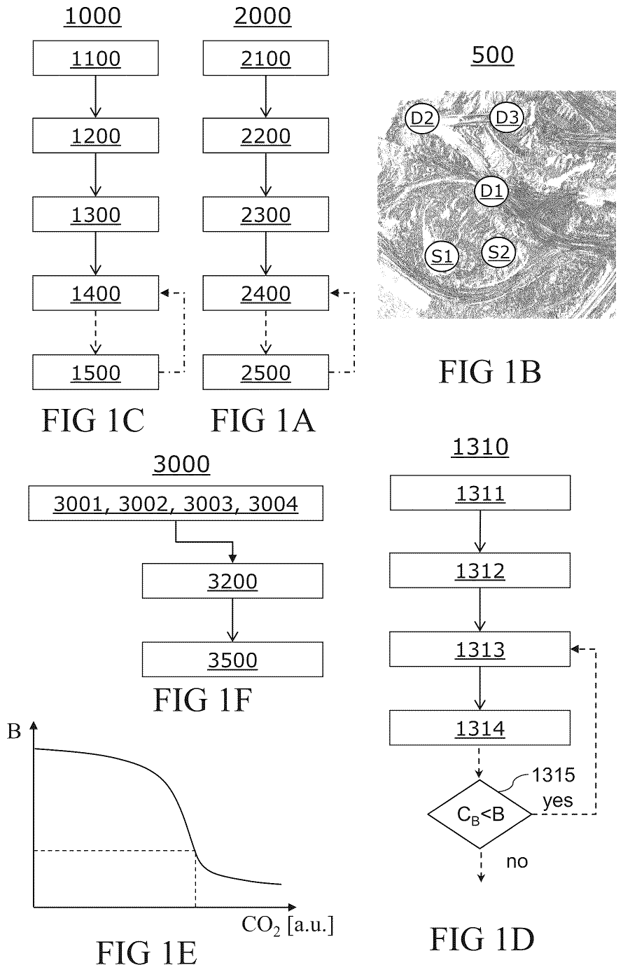

Referring to FIG. 1A, an exemplary method 2000 for setting up an electrical transportation infrastructure of an exemplary mine 500 as shown in FIG. 1B (at a particular time, with source locations S1, S2 and destination location D1, D2, D3 connected with each other via unpaved roads) is explained. In block 2100, (previously collected) mining data for the mine 500 are received.

For each of subsequent time periods of a given mining time interval, for example the (remaining) expected overall mining time of the mine, the mining data include respective expected source locations S1, S2, where a material is to be taken from (excavated), and one or more respective destination location D1, D2, D3 where the material is to be taken (transported) to, for example stockpile(s) and crusher(s). In particular, the source location(s) S1, S2, but also the destination location(s) D1, D2, D3 may change over time. The source locations S1, S2 and the destination locations D1, D2, D3 may be considered as nodes (vertices) of a network or graph for the material transport during the respective time period.

In a subsequent block 2200, the mining data are used to determine a time-dependent 3D network of the mine 500. The time-dependent 3D network may, for each of the subsequent time periods, be represented by a respective network of (available) paths (forming edges of the respective network) connecting the source location(s) with the destination location(s) (forming nodes of the respective network) during the respective time period. For example, the time-dependent 3D network may include and/or be represented by two or more, typically a plurality of time-independent (road) networks for the respective time periods. Alternatively or in addition, the time-dependent 3D network may include and/or be represented by a single (road) network of paths connecting the source location(s) S1, S2 with the destination location(s) D1, D2 during any of the time periods, and information on which of the time periods each path is present/to be used for material transportation.

In a subsequent block 2300, the time-dependent 3D network is used to numerically determine a planned placement of the electrical transportation infrastructure for mine 500, trolleys in the exemplary embodiment, so that expected total costs of the mine 500 over the given mining time interval are at least approximately minimized and mining constraints during the given mining time interval are met as good as possible (for example, at least substantially met).

The expected total costs of the mine include estimated environmental costs resulting from transporting the material between the expected source and destination locations S1, S2, D1, D2, D3 during the given mining time interval. Particularly, the expected total costs of the mine may be formed by the sum of the estimated environmental costs and any other (expected) OpEx and CapEx of mine 500 during the given mining time interval.

In a subsequent block 2400, the electrical transportation infrastructure for the mine 500 is built in place and adapted over time if necessary (as indicated by the dashed-dotted arrow in FIG. 1A), in accordance with the numerically determined planned placement of the electrical transportation infrastructure.

In block 2500, the material may be transported during the mining process from source to destination locations S1, S2, D1, D2, D3 and, if desired, between the destination locations D1, D2, D3 using the electrical transportation infrastructure of the mine.

Referring to FIG. 1C, another exemplary method 1000 for setting up an electrical transportation infrastructure of exemplary mine 500 shown in FIG. 1B is explained. Similar as explained above for block 2100 of method 2000, mining data for the mine 500 are received in block 1100 of method 1000. Further, the time-dependent 3D network of mine 500 may be determined in block 1200 at least substantially similar as explained for block 2200. Thereafter, in block 1300, the time-dependent 3D network is used as input for a placement algorithm to numerically determine the planned placement of the electrical transportation infrastructure for mine 500.

In the exemplary embodiment, the placement algorithm at least approximately minimizes estimated environmental costs as a result of transporting the material between the expected source locations S1, S2 and at least one destination location D1, D2, D3 during the given mining time interval taking into account the relevant mining constraints during the given mining time interval such as production capacity of the mine, production efficiency of the mine and similar constraints.

Thereafter, in subsequent blocks 1400 and 1500, the electrical transportation infrastructure for the mine 500 may be built in place and adapted over time if necessary (as indicated by the dashed-dotted arrow in FIG. 1C), and the material may be transported during the mining, respectively. Blocks 1400 and 1500 may at least substantially correspond to blocks 2400 and 2500 explained above with regard to FIG. 1A.

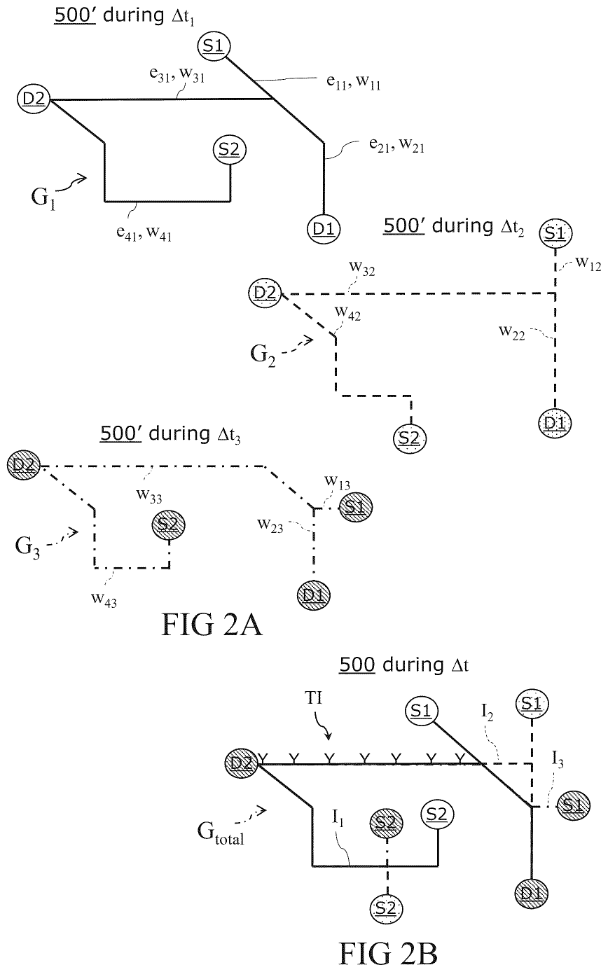

With regard to FIG. 1D and FIGS. 2A to 2B, an exemplary heuristic placement algorithm (method) 1310 for a mine 500′ with source locations S1, S2 and destination locations D1, D2 is explained. Method 1310 may be used in block 1300 of method 1000, but also in block 2300 of method 2000, for determining the planned placement of the electrical transportation infrastructure, which is explained in detail.

In block 1311, for exemplary three subsequent (mining) time periods Δt₁, Δt₂, Δt₃ (Δtⱼ with time index j=1 . . . 3) of mine 500′, a respective weight wᵢⱼ is assigned to each edge eᵢⱼ of the respective networks (network representing graphs) G₁, G₂, G₃ (Gⱼ with j=1 . . . 3, each having exemplary four edges eᵢⱼ, i=1 . . . 4 at time period Δtⱼ) of the time-dependent 3D network. The length of the time periods Δt₁, Δt₂, Δt₃ typically depend on the geological conditions of mine 500′, which may be different, and/or may be in a range from about a month to at least about a year. Note that the desired material transportation routes (haul routes) along the edges eᵢⱼ may change more frequently than the actual (road) network, for example monthly. Thus, the desired haul routes typically determine the length of the time periods Δt₁, Δt₂, Δt₃.

In the exemplary embodiment shown in FIG. 2A, the source locations S1, S2 vary over time while the destination locations D1, D2 are fixed. As further indicated in FIG. 2A, the resulting network networks G₁, G₂, G₃ can also have nodes or vertices for road intersections and between road sections.

The weights wᵢⱼ indicate how desired it is to transport the material along the respective edge eᵢⱼ during the respective time period Δtⱼ using a respective electrical transportation infrastructure at the edge eᵢⱼ (instead of using conventional transportation such as diesel trucks). The weights wᵢⱼ typically depend on multiple factors. For example, the weight can depend on the length and slope (3D-profile) of the edge eᵢⱼ (the longer and steeper the slope, the higher is the weight wᵢⱼ). The weight could also depend on the energy required by (different types of) diesel and electric trucks (the higher the required energy, the higher is the weight wᵢⱼ), as well as the time period Δtⱼ (the longer the time period and/or the earlier the time period (closer in the future/closer to start of mining), the higher is the weight wᵢⱼ).

In this embodiment, the higher the weights wᵢⱼ the more attractive it is to build a trolley line or other electrical infrastructure to supply energy to a vehicle along the edge eᵢⱼ. Other factors that may influence the weights wᵢⱼ are the energy/fuel consumed of an electric/diesel truck when traversing over an edge, the emitted CO₂ of a diesel truck when traversing over an edge, and the cost profile for electricity and fuel.

In block 1312, the networks G₁, G₂, G₃ may be overlaid. The resulting overlay is shown in FIG. 2B. The networks G₁, G₂, G₃ may also be combined and/or merged to form a single network Gₜₒₜₐₗ of paths which connects the expected source locations S1, S2 with the destination location D1, D2 during any of the different time periods Δt₁, Δt₂, Δt₃. The single network Gₜₒₜₐₗ may also be used for planning the placement of the electrical transportation infrastructure of the mine. In this embodiment, (time) information I₁, I₂, I₃ regarding the time periods each path/edge is present (expected to be used for material transport) is additionally required for the planning (optimization). The time information may be stored with or even within the single network Gₜₒₜₐₗ of paths. The time information I₁, I₂, I₃ may in particular be stored as attributes Iⱼ of the paths, particularly as attributes Iⱼ of the edges of the single network formed by the roads connecting the source locations S1, S2 with at least one destination location D1, D2 at the respective time period Δtⱼ (j=1 . . . N with N=3 in the exemplary embodiment). Note that N is typically larger than 10 or even 20.

The time-dependent 3D network Gₜₒₜₐₗ of the mine enriched with the time information may in particular be determined by initializing the time-dependent 3D network Gₜₒₜₐₗ with the source location(s) S1, S2 and destination location(s) D1, D2 of the first network G₁ as nodes (or vertices) connected by the exemplary four edges e₁₁-e₄₁ of G₁. This is repeated for each of the subsequent time periods Δt₂, Δt₃ and according to their chronological order, any node of the subsequent network G₂, G₃ having the same 3D coordinates as one of the node already present in the time-dependent 3D network Gₜₒₜₐₗ is identified. All nodes of the subsequent network G₂, G₃ are added to the time-dependent 3D network Gₜₒₜₐₗ. Any edge eᵢⱼ of the subsequent network G₂, G₃ connecting the same nodes of the time-dependent 3D network Gₜₒₜₐₗ are identified, and information 11, 12, 13 regarding the time period during which the added edges eᵢⱼ are present is added, in particular such that the resulting graph structure/object also stores which edges may be used for material transportation (for any time of mining time interval Δt).

Adding the time information I₁, I₂, I₃ typically includes merging material transportation data of the identified edges eᵢⱼ. Thereafter, the edges may be selected in a greedy manner.

In particular, after block 1312, the edges may be selected from edges eᵢⱼ with highest to lowest wᵢⱼ and build a trolley line TI along each selected edge. This may be continued until the construction cost of the trolley lines TI exceeds an available budget B for the exemplary trolley line TI shown in FIG. 2B. In the exemplary embodiment, the trolley line TI is only (to be) built at a section of the road between destination location D2 and the crossing with the road between source location S1 and destination location D2 during the first mining time period Δt₁, but is also used for material transport during the later time period Δt₂, Δt₃.

In other words, the weights wᵢⱼ may be used to select an edge of the overlay which is most desired to be equipped with a respective electrical transportation infrastructure, in block 1313 of FIG. 1D, and the costs C_{B} for installing the respective electrical transportation infrastructure at the selected edge (or the expected total costs including the costs for installing the respective electrical transportation infrastructure) at the selected edge may be updated, in block 1314. Thereafter, at block 1315, it may be decided depending on whether the respective costs C_{B} are smaller than the budget B or not if the method returns to block 1313 (C_{B}<B) or is finished.

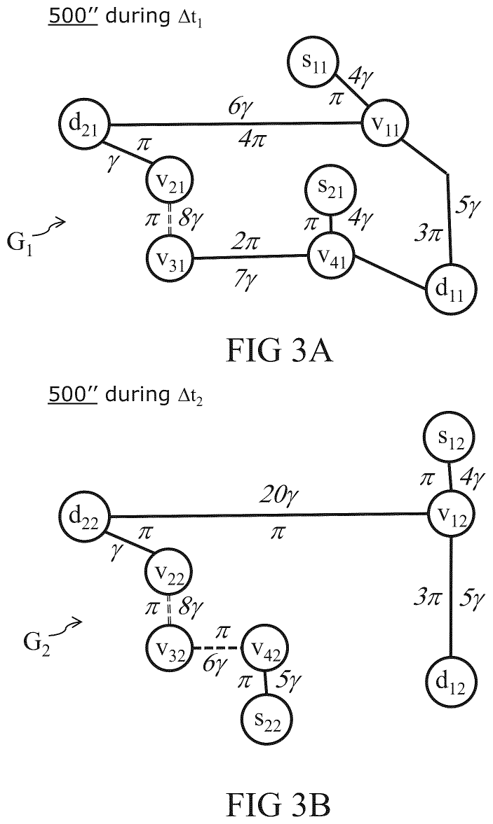

As illustrated in FIG. 1E, method 1310 may be performed for different budgets B to find a good trade-off between the budget B (or costs) and the expected CO₂ emission of the mine. Alternatively to the heuristic approach, a MILP solver may be used for optimization. This is explained in the following with respect to FIGS. 3A, 3B illustrating a mine 500″ also having two source locations s₁ⱼ, s₂ⱼ and two destination locations d₁ⱼ, d₂ⱼ. For the sake of simplicity, there are only two subsequent time periods Δt₁, Δt₂ of the given mining time interval Δt (Δtⱼ with j∈T={1, 2}). The main advantage of using this optimization approach is that it guarantees optimality of the solution. On the other hand, the underlying problem is quite complex and may require many binary/integer variables to formulate the problem. Thus, solving may require a lot of computing power.

In the following, it is demonstrated how a dynamic trolley line placement problem (material transport on mine 500″ is changing over time) can be modeled and solved by MILP formulation. To this end, we consider a simple dynamic trolley line placement problem. The two transport networks are defined via graphs Gⱼ=(Vⱼ, Eⱼ) for j∈{1, 2}. The vertices and edges, and thus the entire graphs, are given by the FIGS. 3A, 3B for time periods Δt₁, Δt₂.

The graph G₁ is given by vertices V₁ and edges E₁:

$${V}_{1} = \{ {s}_{11} , {d}_{21} , {v}_{11} , {v}_{21} , {s}_{21} , {v}_{31} , {v}_{41} , {d}_{11} \}$$

$${E}_{1} = \{ \{ {s}_{11} , {v}_{11} \} , \{ {v}_{11} , {d}_{11} \} , \{ {d}_{11} , {v}_{41} \} , \{ {s}_{21} , {v}_{41} \} , \{ {v}_{41} , {v}_{31} \} , \{ {v}_{31} , {v}_{21} \} , \{ {v}_{21} , {d}_{21} \} , \{ {d}_{21} , {v}_{11} \} \}$$

The graph G₂ is given by vertices V₂ and edges E₂:

$${V}_{2} = \{ {s}_{12} , {d}_{22} , {v}_{12} , {v}_{22} , {v}_{32} , {v}_{42} , {s}_{22} , {d}_{12} \}$$

$${E}_{2} = \{ \{ {s}_{12} , {v}_{12} \} , \{ {v}_{12} , {d}_{12} \} , \{ {s}_{22} , {v}_{42} \} , \{ {v}_{42} , {v}_{32} \} , \{ {v}_{32} , {v}_{22} \} , \{ {v}_{22} , {d}_{22} \} , \{ {v}_{12} , {d}_{22} \} \}$$

Note that in G₁ and G₂, the second index corresponds to the time and is thus always 1 and 2, respectively. For convenience, for an edge e₁∈E₁, we write e₁∈E₂ if the road, corresponding to e₁∈E₁, is still present in E₂. This applies for e₁={v₃₁, v₂₁} and e₁={v₂₁, d₂₁}.

In the following, there are two identical trucks considered. They are referred to by k∈K={1,2}. The mapping SD (k,t)→Eₜ defines on which edges truck k is assigned to travel at time j (during time period Δtⱼ) according to a given production schedule (plan). In the exemplary embodiment, the mapping is defined as follows:

$$SD ( 1 , 1 ) = \{ \{ {s}_{11} , {v}_{11} \} , \{ {v}_{11} , {d}_{11} \} \}$$

$$SD ( 2 , 1 ) = \{ \{ {s}_{21} , {v}_{41} \} , \{ {v}_{41} , {v}_{31} \} , \{ {v}_{31} , {v}_{21} \} , \{ {v}_{21} , {d}_{21} \} \}$$

$$SD ( 1 , 2 ) = \{ \{ {s}_{12} , {v}_{12} \} , \{ {v}_{12} , {d}_{12} \} \}$$

$$SD ( 2 , 2 ) = \{ \{ {s}_{22} , {v}_{42} \} , \{ {v}_{42} , {v}_{32} \} , \{ {v}_{32} , {v}_{22} \} , \{ {v}_{22} , {d}_{22} \} \}$$

Note that edges {v₁₁, d₁₁} and {v₁₂, d₂₂} are obsolete as no truck traverses over them according to the production schedule. The function C(eⱼ) indicates the costs of building a trolley line on edge eⱼ∈Eⱼ. In the exemplary embodiment, these costs (where π>0 is a scaling factor) are given by:

$$C ( \{ {s}_{11} , {v}_{11} \} ) = π$$

$$C ( \{ {v}_{11} , {d}_{11} \} ) = 3$$

$$C ( \{ {d}_{21} , {v}_{11} \} ) = 4$$

$$C ( \{ {s}_{21} , {v}_{41} \} ) = π$$

$$C ( \{ {v}_{41} , {v}_{31} \} ) = 2$$

$$C ( \{ {v}_{31} , {v}_{21} \} ) = C ( \{ {v}_{32} , {v}_{22} \} ) = π$$

$$C ( \{ {v}_{21} , {d}_{21} \} ) = C ( \{ {v}_{22} , {d}_{22} \} ) = π$$

$$C ( \{ {s}_{12} , {v}_{12} \} ) = π$$

$$C ( \{ {s}_{22} , {v}_{42} \} ) = 3 n$$

$$C ( \{ {d}_{22} , {v}_{12} \} ) = π$$

$$C ( \{ {v}_{42} , {v}_{32} \} ) = π$$

$$C ( \{ {s}_{22} , {v}_{42} \} ) = π$$

Note that the cost typically depend on many aspects (for example length of a road, elevation, ground material, accessibility) as already explained above. Thus, it is not to be assumed that the costs, which are also shown next to the respective edge in FIGS. 3A, 3B, have a somewhat linear relationship with the visual length of the edge in the figures.

The function CO2(eⱼ) indicates the CO₂ emissions of a vehicle traversing over an edge eⱼ∈Eⱼ, if there is no trolley line. If there is a trolley line, we assume that the CO₂ emission is 0. In the exemplary embodiment, these costs (where γ>0 is a scaling factor) are given by:

$$CO 2 ( \{ {s}_{11} , {v}_{11} \} ) = 4 γ$$

$$CO 2 ( \{ {v}_{11} , {d}_{11} \} ) = 5 γ$$

$$CO 2 ( \{ {d}_{21} , {v}_{11} \} ) = 6 γ$$

$$CO 2 ( \{ {s}_{21} , {v}_{41} \} ) = 4 γ$$

$$CO 2 ( \{ {v}_{41} , {v}_{31} \} ) = 7 γ$$

$$CO 2 ( \{ {v}_{31} , {v}_{21} \} ) = C ( \{ {v}_{32} , {v}_{22} \} ) = 8 γ$$

$$CO 2 ( \{ {v}_{21} , {d}_{21} \} ) = C ( \{ {v}_{22} , {d}_{22} \} ) = γ$$

$$CO 2 ( \{ {s}_{12} , {v}_{12} \} ) = 4 γ$$

$$CO 2 ( \{ {s}_{22} , {v}_{42} \} ) = 5 γ$$

$$CO 2 ( \{ {d}_{22} , {v}_{12} \} ) = 20 γ$$

$$CO 2 ( \{ {v}_{42} , {v}_{32} \} ) = 6 γ$$

$$CO 2 ( \{ {s}_{22} , {v}_{42} \} ) = 5 γ$$

Note that the CO₂ emissions/CO₂ costs, which are also shown next to the respective edge in FIGS. 3A, 3B, may also depend on many variables. Thus, it is also not to be expected that the CO₂ emissions have a linear relationship with the visual length of the edge in the FIGS. 3A, B. A budget B is given that can be spent at time j=1 (once, for time period Δt₁, typically immediately before or at the beginning of time period Δt₁ in the exemplary embodiment) to build a trolley line. The dynamic trolley line placement problem is then to decide which trolley lines should be built on which edges at time j=1 (for time period Δt₁) such that the available budget B is not exceeded and such that the overall CO₂-emission, which is expected to be based on the production schedule over the lifetime of the mine, is minimized.

To formulate this problem, we introduce binary variables xₑ_{ⱼ}∈{0,1} for eⱼ∈Eⱼ, which are equal to 1 if a trolley line should be built at time j (for time period Δtⱼ) and zero otherwise. Additionally, we introduce binary variables yₑ_{ⱼ}∈{0,1} for eⱼ∈Eⱼ, which are equal to 1 if a trolley line has been built at time j or (only applicable if j=2 and if the edge exists in both graphs G₁ and G₂) has already been built at time j−1 (for time period Δtⱼ₋₁) and zero otherwise. Then, the dynamic trolley line placement problem can be formulated as follows:

$${min}_{{x}_{{e}_{j}} , {y}_{{e}_{j}} ∈ \{ 0 , 1 \}} {\sum }_{j ∈ \{ 1 , 2 \}} {\sum }_{k ∈ K} {\sum }_{{e}_{j} ∈ SD ( k , j )} CO 2 ( {e}_{j} ) \times ( 1 - {y}_{{e}_{j}} )$$

$${\sum }_{j ∈ \{ 1 , 2 \}} {\sum }_{{e}_{j} ∈ {E}_{j}} {\sum }_{k ∈ K} C ( {e}_{j} ) \times {x}_{j} \leq B \qquad ( 1 )$$

$${y}_{{e}_{j}} = {x}_{{e}_{j}} for {e}_{j} ∈ ( {E}_{1} ⋃ {E}_{2} ) ∖ \{ \{ {v}_{32} , {v}_{22} \} , \{ {v}_{12} , {d}_{12} \} \} \qquad ( 2 )$$

$${y}_{\{ {v}_{32} , {v}_{22} \}} = {x}_{\{ {v}_{31} , {v}_{21} \}} + {x}_{\{ {v}_{32} , {v}_{22} \}} \qquad ( 3 )$$

$${y}_{\{ {v}_{12} , {d}_{12} \}} = {x}_{\{ {v}_{21} , {d}_{21} \}} + {x}_{\{ {v}_{12} , {d}_{12} \}} \qquad ( 4 )$$

$${x}_{{e}_{j}} ∈ \{ 0 , 1 \} , {y}_{{e}_{j}} ∈ \{ 0 , 1 \} for {e}_{j} ∈ {E}_{j}$$

In the objective function, the total CO₂-emissions over the lifetime of the mine are minimized. CO₂ is only emitted, if a vehicle travels over a road with no trolley line, that is, if yₑ_{ⱼ}=0. In Constraint (1), the construction costs C for building trolley lines are ensured to stay within the available budget B. For the two roads, that do not change from j=1 to j=2, Equations (3) and (4) ensure that a trolley line built at time j=1 remains in place also at j=2. All other roads only exist either for j=1 or for j=2. For these edges, variables xₑ_{ⱼ} and Yes are to be equal (see Equation (2)). This Mixed Integer Linear Programming formulation can then be solved using a MILP solver (for example Gurobi, CPLEX, Highs, or CBC).

In the present embodiment, the optimal solution is obtained for x_{{v31,v21}}=x_{{v32,v42}}=1 with all other xₑ_{ⱼ} variables set to 0. Thus, there is a trolley line built at the road corresponding to edge {v₃₁, v₂₁} in G₁ at time j=1 (dashed double line in FIG. 3A, 3B). This is also intuitive as traversing over this road has a high CO₂ cost (8γ) and the road is present in both time periods.

Another trolley line is built at the new road corresponding to edge {v₃₂, v₄₂} in G₂ at time j=2 (dashed line in FIG. 3A, 3B). Note, that, as this trolley line is only built at time j=2, it does not have an impact on the CO₂ emission at j=1. However, this road is new and contributes high CO₂ emissions (6γ). Therefore, it is better to wait until j=2 to invest the budget to build a trolley line along this edge. Both trolley lines cost 2π, which is the full budget. The CO₂ emissions for j=1 are 4γ+5γ=9γ and γ+0+7γ+4γ=12γ for vehicles 1 and 2, respectively, which is 21γ in total.

Similarly, the CO₂ emissions for j=2 are 4γ+5γ=9γ and γ+0+0+5γ=6γ for vehicles 1 and 2, respectively, which is 15γ in total. Thus, the optimal construction of a trolley line leads to an overall minimized CO₂ emission of 15γ over the given mining time interval (lifetime of a mine).

Referring now to FIG. 1F, an exemplary method 3000 of mining in a mine as shown in FIG. 1B is explained. In the first blocks, mining data relating to the mine 500 may be determined (in block 3001), stored in a database (in block 3002), and/or received in a block 3003, for example, from the database. Further, in accordance with the mining data, in particular expected life times of expected source locations S1, S2 of the mine 500, time periods may be selected, in block 3004. In a subsequent block 3200, an electrical transportation infrastructure TI of the mine 500 may be determined and set up as explained above. Thereafter, material may be transported using the electrical transportation infrastructure of the mine, in block 3500.

The disclosed systems and methods are not limited to the specific embodiments described herein. Rather, components of the systems or activities of the methods may be utilized independently and separately from other described components or activities.

This written description uses examples to disclose various embodiments, which include the best mode, to enable any person skilled in the art to practice those embodiments, including making and using any devices or systems and performing any incorporated methods. The patentable scope is defined by the claims and may include other examples that occur to those skilled in the art. Such other examples are intended to be within the scope of the claims if they have structural elements that do not differ from the literal language of the claims, or if they include equivalent structural elements with insubstantial differences form the literal language of the claims.

1-28. (canceled)

29. A method for setting up an electrical transportation infrastructure of a mine, the method comprising:
receiving mining data for the mine, for different time periods of a given mining time interval, the mining data comprising respective expected source locations, where a material is to be taken from, and at least one respective destination location, where the material is to be taken to;
determining, using the mining data, a time-dependent 3D network of the mine, the time-dependent 3D network comprising at least one of:
for each of the different time periods, a respective network of paths connecting the expected source locations with the at least one destination location during the respective time period; and
a single network of paths connecting the expected source locations with the at least one destination location during any of the different time periods, and information during which of the time periods each path is present;
numerically determining, using the time-dependent 3D network, a planned placement of the electrical transportation infrastructure so that expected total costs of the mine over the given mining time interval are at least approximately minimized, the expected total costs of the mine comprising estimated environmental costs resulting from transporting the material between the expected source locations and the at least one destination location during the given mining time interval subject to mining constraints during the given mining time interval; and
initializing placing the electrical transportation infrastructure in the mine based on the planned placement of the electrical transportation infrastructure.

30. The method of claim 29, wherein numerically determining the planned placement of the electrical transportation infrastructure comprises using a placement algorithm, the placement algorithm at least approximately minimizing the estimated environmental costs resulting from transporting the material between the expected source locations and the at least one destination location during the given mining time interval for a given budget of the electrical transportation infrastructure, wherein the planned placement of the electrical transportation infrastructure is determined such that expected total costs of the mine over the given mining time interval are at least approximately minimized, wherein the expected total costs of the mine comprise capital expenditures (CapEx) of the mine, and operating expenses (OpEx) of the mine, wherein the CapEx of the mine comprise CapEx of the electrical transportation infrastructure provided by a first portion of the estimated environmental costs, and the OpEx of the mine comprise OpEx of the electrical transportation infrastructure provided by a second portion of the estimated environmental costs, and/or wherein the environmental costs refer to at least one of greenhouse gas (GHG) emissions and carbon dioxide emissions.

31. A method for setting up an electrical transportation infrastructure of a mine, the method comprising:
receiving mining data for the mine, for different time periods of a given mining time interval, the mining data comprising respective expected source locations, where a material is to be taken from, and at least one respective destination location, where the material is to be taken to;
determining, using the mining data, a time-dependent 3D network of the mine, the time-dependent 3D network comprising at least one of:
for each of the different time periods, a respective network of paths connecting the expected source locations with the at least one destination location during the respective time period, and
a single network of paths connecting the expected source locations with the at least one destination location during any of the different time periods, and information during which of the time periods each path is present;
numerically determining, for a given budget of the electrical transportation infrastructure and using the time-dependent 3D network, a planned placement of the electrical transportation infrastructure, using a placement algorithm, the placement algorithm at least approximately minimizing estimated environmental costs resulting from transporting the material between the expected source locations and the at least one destination location during the given mining time interval subject to mining constraints during the given mining time interval; and
initializing placing the electrical transportation infrastructure in the mine based on the planned placement of the electrical transportation infrastructure.

32. The method of claim 31, wherein the planned placement of the electrical transportation infrastructure is determined such that expected total costs of the mine over the given mining time interval are at least approximately minimized, wherein the expected total costs of the mine comprise capital expenditures (CapEx) of the mine, and operating expenses (OpEx) of the mine, wherein the CapEx of the mine comprise CapEx of the electrical transportation infrastructure provided by a first portion of the estimated environmental costs, and the OpEx of the mine comprise OpEx of the electrical transportation infrastructure provided by a second portion of the estimated environmental costs, and/or wherein the environmental costs refer to at least one of greenhouse gas (GHG) emissions and carbon dioxide emissions, and/or comprising varying the given budget to at least approximately minimize the expected total costs of the mine over the given mining time interval.

33. The method of claim 30, comprising varying the given budget to at least approximately minimize the expected total costs of the mine over the given mining time interval, wherein the given budget comprises the CapEx of the electrical transportation infrastructure, and the OpEx of the electrical transportation infrastructure during the given mining time interval such as expected energy costs for transporting the material using the electrical transportation infrastructure, and/or wherein the OpEx of the mine comprises expected energy costs for transporting the material without using the electrical transportation infrastructure.

34. The method of claim 29, wherein the method comprises providing at least one road of the mine which is represented by at least one edge of the time-dependent 3D network with at least one of: an electric power supply for vehicles transporting the material, a conductor rail, a power line, and a trolley line, and/or wherein the electrical transportation infrastructure comprises at least one of: an electric power supply for vehicles transporting the material, conductor rails, power lines and trolley lines.

35. The method of claim 29, wherein the mining constraints refer to at least one of: a transportation time for the material, a production schedule of the mine, a production capacity of the mine, a production efficiency of the mine, and a cost information.

36. The method of claim 30, wherein the placement algorithm is an optimization algorithm comprising respective penalty terms for the given budget of the electrical transportation infrastructure and the environmental costs, and/or wherein the placement algorithm comprises determining a respective placement of the electrical transportation infrastructure for different given budgets.

37. The method of claim 29, wherein the time-dependent 3D network is a time-dependent 3D road network, and/or wherein the placement of the electrical transportation infrastructure is fixed for the given mining time interval.

38. The method of claim 30, wherein the placement algorithm is a heuristic algorithm for numerically determining the planned placement of the electrical transportation infrastructure.

39. The method of claim 38, the placement algorithm comprising at least one of the following activities:
a. assigning a weight for each edge of the respective networks, the weights indicating how desired it is to transport the material on the edges using a respective electrical transportation infrastructure of the edge;
b. determining an overlay of the respective networks;
c. using the weights to select an edge of the overlay which is most desired to be equipped with a respective electrical transportation infrastructure;
d. updating the expected total costs or costs of building the electrical transportation infrastructure in accordance with costs for installing the respective electrical transportation infrastructure at the selected edge; and
e. repeating activities c and d until the expected total cost at least reaches a total budget or the costs of building the electrical transportation infrastructure at least reaches the given budget.

40. The method of claim 39, wherein the weights depend on at least one of: a length of the edge, a slope of the edge, an elevation profile of the edge, the time periods, an expected energy consumption and/or emitted amount GHG for using the electrical transportation infrastructure of the respective edge, and an expected energy consumption and/or emitted amount GHG for using an alternative energy source for transporting the material along the respective edge, in particular a respective fossil fuel consumption, for example a diesel consumption.

41. The method of claim 30, wherein the placement algorithm uses mixed integer linear programming, MILP.

42. The method of claim 41, comprising at least one of:
for each of the different time periods, determining, for each edge of a graph representing the time-dependent 3D network during the respective time period, costs of building the electrical transportation infrastructure at and/or along the edge;
for each of the different time periods, determining, for each edge of the graph, respective costs referring to an emitted GHG amount resulting from transporting the material along the edge when the electrical transportation infrastructure is used and when a non-electrical transportation infrastructure is used such as a diesel truck, in particular a respective emitted CO₂ amount; and
using a MILP solver to minimize a function comprising the costs of building the electrical transportation infrastructure and the costs referring to the emitted GHG at the constrain that a given budget for the electrical transportation infrastructure is not exceeded.

43. The method of claim 29, wherein the given mining time interval is larger than one year, two years or even several years, and/or refers to an expected overall mining time of the mine.

44. The method of claim 29, wherein the single network of paths is determined based on the networks of paths connecting the expected source locations with the at least one destination location during the respective time period, and/or wherein determining, the time-dependent 3D network of the mine comprises:
determining, using the mining data, a first network comprising nodes formed by expected source locations and at least one destination location during a first time period and edges connecting the expected source locations and the at least one destination location during the first time period;
initializing the time-dependent 3D network with the first network; and
for each of the subsequent time periods of the given mining time interval repeating:
determining, using the mining data, a subsequent network comprising nodes formed by expected source locations and at least one destination location during the subsequent time period, and edges connecting the expected source locations and the at least one destination location during the subsequent time period;
identifying any node of the subsequent network having the same 3D coordinates as one of the node already present in the time-dependent 3D network;
adding all nodes of the subsequent network to the time-dependent 3D network;
identifying any edge of the subsequent network connecting the same nodes of the time-dependent 3D network; and
adding information about the time period during which the added edges are present, adding the information typically comprising merging material transportation data of the identified edges.

45. The method of claim 29, wherein the information on which of the time periods each path is present is stored within the single network of paths, in particular as attributes of the path, more particular as attributes of the edges of the single network formed by roads connecting the source locations with at least one destination location at the respective time period.

46. The method of claim 29, wherein the method comprises at least one of: setting up the electrical transportation infrastructure in the mine, and changing the electrical transportation infrastructure during the given mining time interval, wherein the method is a computer-implemented method, and/or wherein initializing placing the electrical transportation infrastructure in the mine comprises:
at least coordinating building the electrical transportation infrastructure based on the planned placement of the electrical transportation infrastructure, and/or at least coordinating changing the electrical transportation infrastructure during the given mining time interval based on the planned placement of the electrical transportation infrastructure.

47. A method of mining in a mine, the method comprising at least one of:
determining mining data relating to the mine;
storing the mining data in a database;
receiving the mining data from the database; and
selecting the time periods in accordance with expected life times of expected source locations of the mine, the method further comprising:
setting up an electrical transportation infrastructure of the mines, setting up the electrical transportation infrastructure of the mine comprising:
receiving mining data for the mine, for different time periods of a given mining time interval, the mining data comprising respective expected source locations, where a material is to be taken from, and at least one respective destination location, where the material is to be taken to;
determining, using the mining data, a time-dependent 3D network of the mine, the time-dependent 3D network comprising at least one of:
for each of the different time periods, a respective network of paths connecting the expected source locations with the at least one destination location during the respective time period; and
a single network of paths connecting the expected source locations with the at least one destination location during any of the different time periods, and information during which of the time periods each path is present;
numerically determining, using the time-dependent 3D network, a planned placement of the electrical transportation infrastructure so that expected total costs of the mine over the given mining time interval are at least approximately minimized, the expected total costs of the mine comprising estimated environmental costs resulting from transporting the material between the expected source locations and the at least one destination location during the given mining time interval subject to mining constraints during the given mining time interval; and
initializing placing the electrical transportation infrastructure in the mine based on the planned placement of the electrical transportation infrastructure; and
transporting the material using the electrical transportation infrastructure of the mine.

48. The method of claim 47, wherein method is at least partly performed by a planning system for the mine, wherein the mine comprises a time-dependent road network comprising edges formed by roads connecting the expected source locations with the respective destination locations, wherein setting up the electrical transportation infrastructure of the mine comprises providing at least one edge of the road network with at least one of: an electric power supply for vehicles transporting the material, a conductor rail, a power line, and a trolley line, wherein setting up the electrical transportation infrastructure of the mine is performed prior to starting mining the material, and/or after starting mining the material, in particular after detecting an unexpected material quality at one of the expected source locations of the mine and/or regularly.
